(19) United States
(12) Patent Application Publication
(10) Pub. No.: US 2024/0348008 A1
(43) Pub. Date: Oct. 17, 2024

(54) VERTICAL CAVITY SURFACE EMITTING LASER DEVICE WITH AN INTEGRATED GROUND LAYER

(71) Applicant: Lumentum Operations LLC, San Jose, CA (US)

(72) Inventors: Siu Kwan CHEUNG, San Jose, CA (US); Lijun ZHU, Dublin, CA (US); Matthew Glenn PETERS, Menlo Park, CA (US); Jacob U. LOPEZ RUVALCABA, Albuquerque, NM (US)

(21) Appl. No.: 18/335,937

(22) Filed: Jun. 15, 2023

Related U.S. Application Data
(60) Provisional application No. 63/496,094, filed on Apr. 14, 2023.

(51) Int. Cl. H01S 5/042; H01S 5/02315; H01S 5/0234; H01S 5/183; H01S 5/42; H05K 1/02

(52) U.S. Cl. CPC H01S 5/04256; H01S 5/02315; H01S 5/0234; H01S 5/18305; H01S 5/423; H05K 1/0218

(57) ABSTRACT

In some implementations, a vertical cavity surface emitting laser (VCSEL) device includes a substrate and a plurality of VCSELs on the substrate. The VCSEL device may include an anode layer on the substrate and electrically connected to the plurality of VCSELs. The VCSEL device may include a cathode electrode over at least a portion of one or more VCSELs, of the plurality of VCSELs, and electrically connected to the one or more VCSELs. The VCSEL device may include a ground layer electrically isolated from the at least one anode layer and the cathode electrode by one or more isolation layers, wherein the ground layer is on the anode layer and the cathode electrode, between the anode layer and the cathode electrode, or underneath the anode layer.

### CROSS-REFERENCE TO RELATED APPLICATION

This Patent Application claims priority to U.S. Provisional Patent Application No. 63/496,094, filed on Apr. 14, 2023, and entitled “ON-CHIP GROUND LOOP RETURN PATH FOR A VERTICAL CAVITY SURFACE EMITTING LASER ARRAY.” The disclosure of the prior Application is considered part of and is incorporated by reference into this Patent Application.

### TECHNICAL FIELD

The present disclosure relates generally to vertical cavity surface emitting lasers (VCSELs) and to a VCSEL device with an integrated ground layer.

### BACKGROUND

A vertical-emitting laser device, such as a VCSEL, is a laser in which a beam is emitted in a direction perpendicular to a surface of a substrate (e.g., vertically from a surface of a semiconductor wafer). Multiple vertical-emitting devices may be arranged in an array with a common substrate.

### SUMMARY

In some implementations, an emitter assembly includes a carrier including a ground plane, a decoupling capacitor electrically connected to the ground plane, and a vertical cavity surface emitting laser (VCSEL) device on the carrier and electrically connected to the ground plane and the decoupling capacitor. The VCSEL device may include a substrate and a plurality of VCSELs on the substrate. The VCSEL device may include at least one anode layer on the substrate and electrically connected to the plurality of VCSELs. The VCSEL device may include one or more first interconnects that electrically connect the at least one anode layer and the carrier. The VCSEL device may include a cathode electrode over at least a portion of one or more VCSELs, of the plurality of VCSELs, and electrically connected to the one or more VCSELs. The VCSEL device may include one or more second interconnects that electrically connect the cathode electrode and the carrier. The VCSEL device may include a ground layer electrically connected to the ground plane and electrically isolated from the at least one anode layer and the cathode electrode by one or more isolation layers. The VCSEL device may include one or more third interconnects that electrically connect the ground layer and the carrier.

In some implementations, an emitter assembly includes a carrier including a ground plane, a decoupling capacitor electrically connected to the ground plane, and a VCSEL device disposed on the carrier and electrically connected to the ground plane and the decoupling capacitor. The VCSEL device may include a substrate and a plurality of VCSELs on the substrate. The VCSEL device may include an anode layer on the substrate, where current to be discharged from the decoupling capacitor is to flow through the anode layer in a first direction. The VCSEL device may include a cathode electrode over at least a portion of one or more VCSELs of the plurality of VCSELs, where current is to flow from the anode layer through the one or more VCSELs to the cathode electrode, and from the cathode electrode to the carrier. The VCSEL device may include a ground layer electrically isolated from the anode layer and the cathode electrode by one or more isolation layers, where current returning from the carrier is to flow through the ground layer in a second direction opposite the first direction.

In some implementations, a VCSEL device includes a substrate and a plurality of VCSELs on the substrate. The VCSEL device may include an anode layer on the substrate and electrically connected to the plurality of VCSELs. The VCSEL device may include a cathode electrode over at least a portion of one or more VCSELs, of the plurality of VCSELs, and electrically connected to the one or more VCSELs. The VCSEL device may include a ground layer electrically isolated from the at least one anode layer and the cathode electrode by one or more isolation layers, wherein the ground layer is on the anode layer and the cathode electrode, between the anode layer and the cathode electrode, or underneath the anode layer.

### BRIEF DESCRIPTION OF THE DRAWINGS

FIGS. 1A and 1B are diagrams illustrating a top-view of an example of a conventional emitter and a cross-sectional view of the example emitter along line X-X, respectively.

FIG. 2 is a diagram illustrating a perspective view of an example emitter assembly.

FIG. 3 is a diagram illustrating a perspective view of an example VCSEL device.

FIG. 4 is a diagram illustrating a cross-sectional view of the example VCSEL device of FIG. 2 taken along line A-A.

FIG. 5 is a diagram illustrating a cross-sectional view of the example VCSEL device shown in FIG. 4, taken along line B-B.

FIG. 6 is a diagram illustrating a cross-sectional view of the example emitter assembly of FIG. 2 taken along line C-C.

FIG. 7 is a flowchart of an example process associated with manufacturing a VCSEL device with an integrated ground layer.

### DETAILED DESCRIPTION

The following detailed description of example implementations refers to the accompanying drawings. The same reference numbers in different drawings may identify the same or similar elements.

A bottom-emitting VCSEL device (e.g., a VCSEL chip) may be flip chip mounted on an integrated circuit (IC) driver chip (which may be referred to as a VCSEL-on-driver (VOD) configuration). VCSELs of the VCSEL device may be turned on and off via the driver chip. A decoupling capacitor may also be included with the driver chip and electrically connected to the VCSEL device. In this configuration, current is discharged from the decoupling capacitor to an anode electrode of the VCSEL device, through one or more VCSELs of the VCSEL device, and to a cathode electrode of the VCSEL device. The cathode current may then flow to an edge of the VCSEL device, down to the driver chip, and to a ground contact of the decoupling capacitor. Thus, transient looping current may circulate on a surface of the driver chip or in one or more redistribution layers on the driver chip with a large cross-sectional area encapsulated by the current loop of the driving current where the inductive magnetic energy is stored, and therefore may provide insignificant or small mutual inductance cancellation with respect to the driving current that flows through the anode electrode.

As a result, parasitic inductance along current paths through the VCSEL device may be high. This high parasitic inductance may cause difficulties in achieving high-speed operation of the VCSEL device and may otherwise constrain a performance of the VCSEL device. Furthermore, routing ground looping current externally from the VCSEL device (e.g., on a surface of the driver chip or in one or more redistribution layers on the driver chip) may increase overall package size.

Some implementations described herein provide a VCSEL device, and an emitter assembly including the VCSEL device, with a ground current looping return path at the VCSEL device (e.g., an on-chip return path). In some implementations, the VCSEL device may include a plurality of VCSELs, an anode layer for the plurality of VCSELs, a cathode electrode for one or more of the VCSELs, and a ground layer electrically isolated from the anode layer and the cathode electrode. For example, the ground layer may be arranged on top of the anode layer and the cathode electrode, and electrically isolated from the anode layer and the cathode electrode by an isolation layer. The ground layer may provide a current looping path near to, but in an opposite direction to, a driving current path during transient response through the anode layer. Accordingly, current flowing through the ground layer may provide mutual inductance cancellation with current flowing through the anode layer (e.g., when the isolation layer between the anode layer and the ground layer is sufficiently thin). This mutual inductance cancellation may lower inductance in the driving current path through the anode layer (e.g., approximately five times lower than what the inductance would be without the ground layer), thereby improving a performance of the VCSEL device (e.g., including faster response time and improved pulse shape) and facilitating high-speed operation of the VCSEL device. For example, due to the lower inductance, a rise time for the VCSEL device may be on a sub-nanosecond scale. Furthermore, the ground layer being integrated into the VCSEL device provides denser component integration, provides a more compact looping area, and facilitates a reduction of external routing for the VCSEL device to reduce an overall package size. The ground layer may also provide improved heat spreading for the VCSEL device and/or may lower a thermal resistance of the VCSEL device.

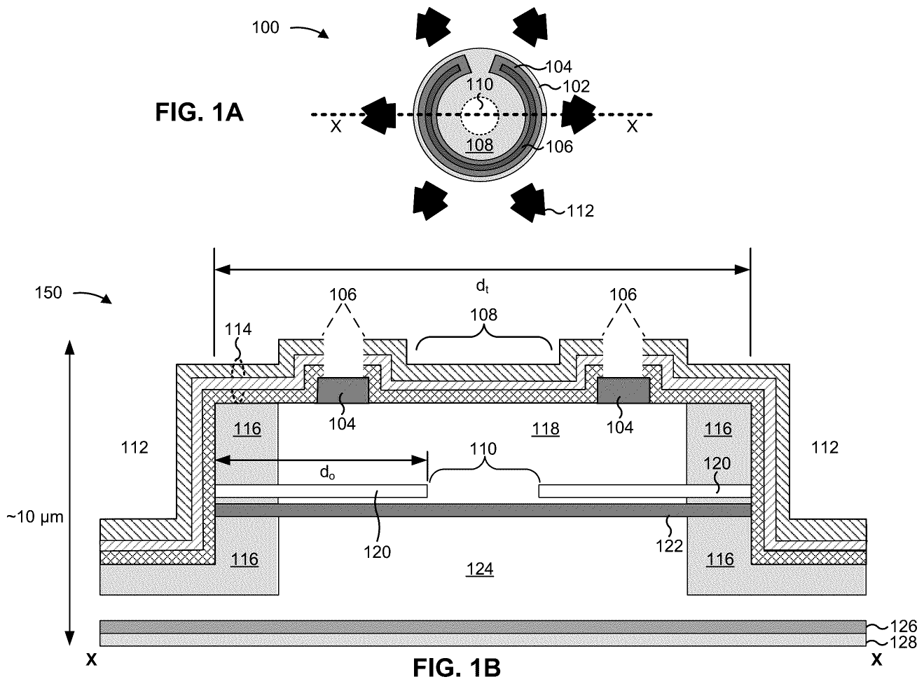

FIGS. 1A and 1B are diagrams illustrating a top-view of an example of a conventional emitter 100 and a cross-sectional view 150 of the example emitter 100 along line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g., a dielectric layer, a passivation layer, or a dielectric mirror composed of multiple layers) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium gray area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112 (e.g., of the same size or of different sizes), in practice, other configurations may be used, such as a compact emitter that includes five trenches 112, seven trenches 112, or another quantity of trenches. In some implementations, trenches 112 may encircle emitter 100 to form a mesa structure di (shown in FIG. 1B). As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are contemplated. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, emitter 100 may have, for example, a total height that is approximately 10 micrometers (μm).

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al₂O₃ layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer, and which may act as an additional DBR. For example, protective layer 114 may include one or more sub-layers (e.g., a dielectric passivation layer and/or a mirror layer, a SiO₂ layer, a Si₃N₄ layer, an Al₂O₃ layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor, may provide a non-rectifying electrical junction, and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B are provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100, and any layer may comprise more than one layer. For example, in a bottom-emitting VCSEL, cathode layer 128 may be on a top side of emitter 100 over, and electrically connected to, top mirror 118, thereby eliminating optical aperture 108. Cathode layer 128 may be underneath protective layer 114, on top of protective layer 114 (e.g., where cathode layer 128 is electrically connected to top mirror 118 through vias 106), or protective layer 114 may be eliminated. Furthermore, the anode ohmic metal layer 104 may be relocated underneath bottom mirror 124 so as to allow current to flow from ohmic metal layer 104 to cathode layer 128 through active region 122 and to allow light emission through substrate 128. Ohmic metal layer 104 and cathode layer 128 may be electrically isolated from each other by an isolation material (e.g., a dielectric material).

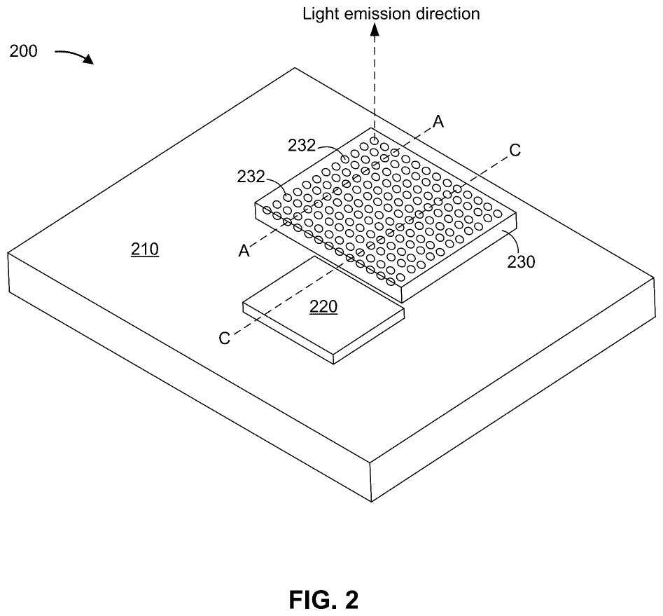

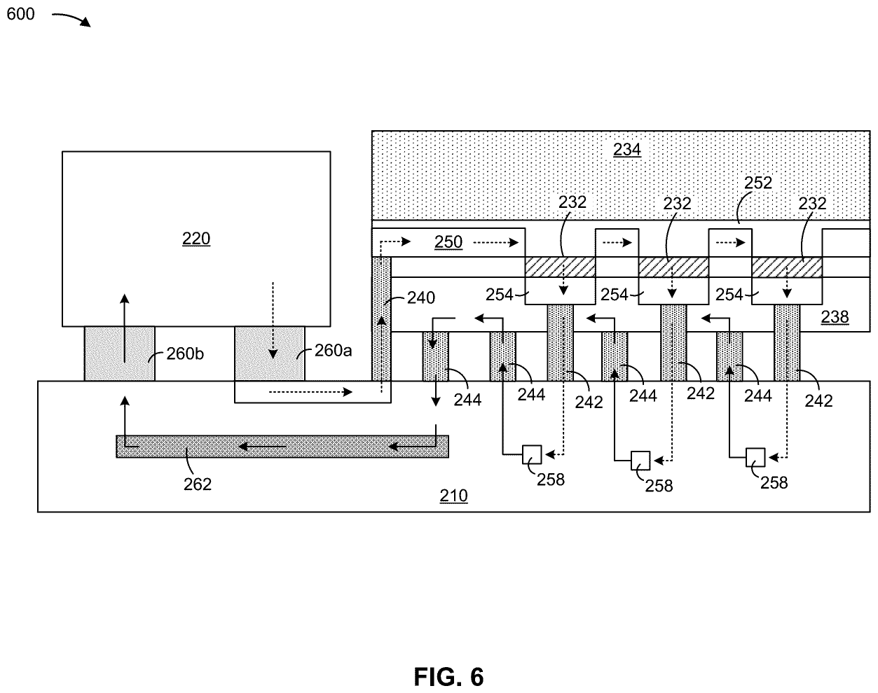

FIG. 2 is a diagram illustrating a perspective view of an example emitter assembly 200. As shown, the emitter assembly 200 includes a carrier 210, a decoupling capacitor 220 (e.g., one or more decoupling capacitors 220), and a VCSEL device 230. The carrier 210 may include an IC chip, such as a driver chip configured to drive the VCSEL device 230. Alternatively, the carrier 210 may include a circuit board (e.g., a printed circuit board) or another substrate for the VCSEL device 230 and the decoupling capacitor 220. In some implementations, the carrier 210 may include one or more redistribution layers (not shown). For example, the carrier 210 may include one or more redistribution layers disposed on a driver chip. The carrier 210 may include a ground plane (shown in FIG. 6). For example, the ground plane may be a metal layer in or on the carrier 210 (e.g., in a redistribution layer of the carrier 210).

The decoupling capacitor 220 may be connected to the carrier 210. For example, the decoupling capacitor 220 may be disposed on the carrier 210 or integrated into the carrier 210. As an example, the decoupling capacitor 220 may be in a flip chip configuration on the carrier 210. The decoupling capacitor 220 may include a set of electrical contacts (shown in FIG. 6). The decoupling capacitor 220 (e.g., a ground contact of the decoupling capacitor 220) may be electrically connected to the ground plane. The decoupling capacitor 220 may be connected to a voltage source (not shown) to charge the decoupling capacitor 220.

The VCSEL device 230 (e.g., a VCSEL chip) may be disposed on the carrier 210. For example, the VCSEL device 230 may be in a flip chip configuration on the carrier 210. The VCSEL device 230 may be electrically connected to the ground plane and to the decoupling capacitor 220. In some implementations, the emitter assembly 200 may omit the decoupling capacitor 220, and the VCSEL device 230 may be connected to the voltage source. The VCSEL device 230 may include a plurality of VCSELs 232 (e.g., an n×m VCSEL array, where n and m are integers greater than one). The VCSEL device 230 may be configured such that VCSELs 232 may be controlled (e.g., driven) individually, as rows, or as clusters. In some implementations, the VCSEL device 230 may be configured for driving multiple VCSELs 232 concurrently at high speed.

As described herein, the VCSEL device 230 may be a part of the emitter assembly 200. In some implementations, the VCSEL device 230 may be a component separate from the emitter assembly 200 (e.g., the VCSEL device 230 may be a standalone device).

As indicated above, FIG. 2 is provided as an example. Other examples may differ from what is described with regard to FIG. 2.

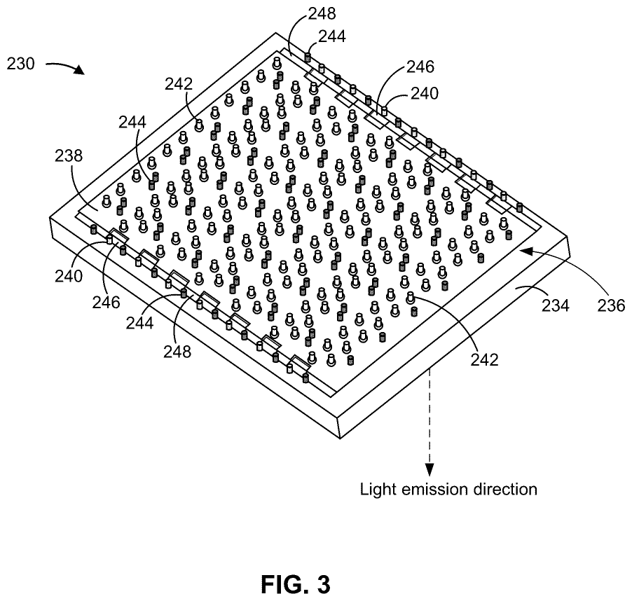

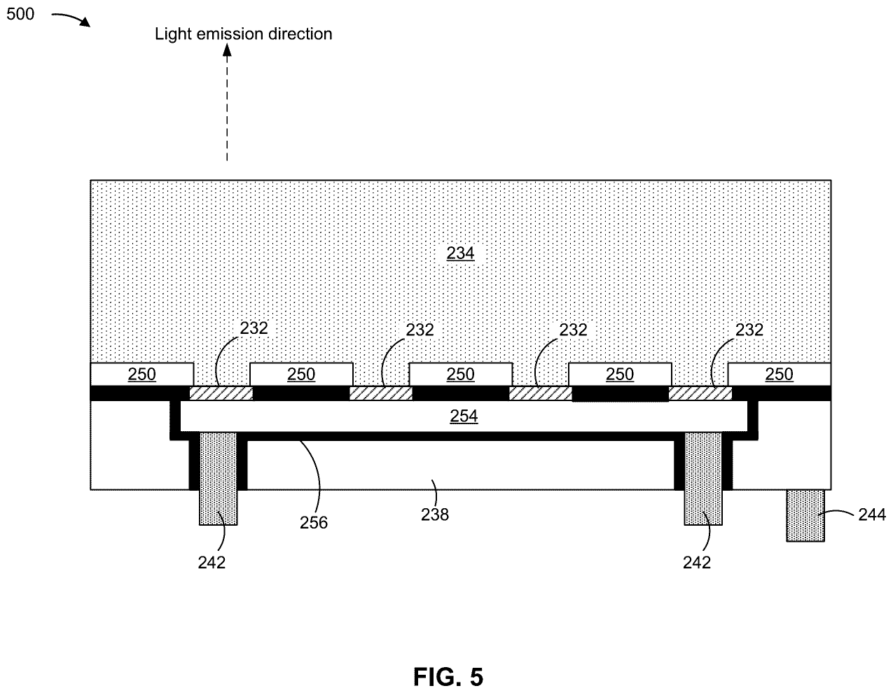

FIG. 3 is a diagram illustrating a perspective view of an example VCSEL device 230. The VCSEL device 230 may include a substrate 234 (e.g., corresponding to substrate layer 126) and a set of layers 236 (e.g., a three-dimensional stack up) disposed on the substrate 234. As described further herein, the set of layers 236 may include a ground layer 238 (e.g., the ground layer 238 may be integrated into the VCSEL device 230). The ground layer 238 may be electrically connected to the ground plane of the carrier 210, as described in connection with FIG. 6. The VCSEL device 230 may have an electrical connection to the carrier 210 via a plurality of interconnects, such as solder balls, conductive bumps (e.g., copper bumps), conductive pillars (e.g., copper pillars), or the like. For example, the interconnects may include one or more (e.g., a plurality of) first interconnects 240 electrically connected to an anode layer (shown in FIGS. 5-6) of the set of layers 236, one or more (e.g., a plurality of) second interconnects 242 electrically connected to one or more cathode electrodes (shown in FIGS. 5-6) of the set of layers 236, and one or more (e.g., a plurality of) third interconnects 244 electrically connected to the ground layer 238. As shown, the third interconnects 244 may extend from a surface of the ground layer 238. Moreover, the ground layer 238 may include one or more (e.g., a plurality of) openings, and the second interconnects 242 may extend respectively through the openings.

In some implementations, the first interconnects 240 may be positioned at one or more edges of the VCSEL device 230 (e.g., electrically connected to contact pads 246 at one or more edges of the anode layer). In some implementations, the second interconnects 242 may be arranged in rows, each row corresponding to a row of VCSELs 232 that share a common cathode electrode. In some implementations, the third interconnects 244 may be positioned at one or more edges of the VCSEL device 230 (e.g., electrically connected to contact pads 248 at one or more edges of the ground layer 238) alternating with the first interconnects 240, and/or may be arranged between rows of the second interconnects 242. For example, the contact pads 246 may alternate with the contact pads 248. The contact pads 246 and the contact pads 248 may be separated from each other, or otherwise electrically isolated from each other.

As indicated above, FIG. 3 is provided as an example. Other examples may differ from what is described with regard to FIG. 3.

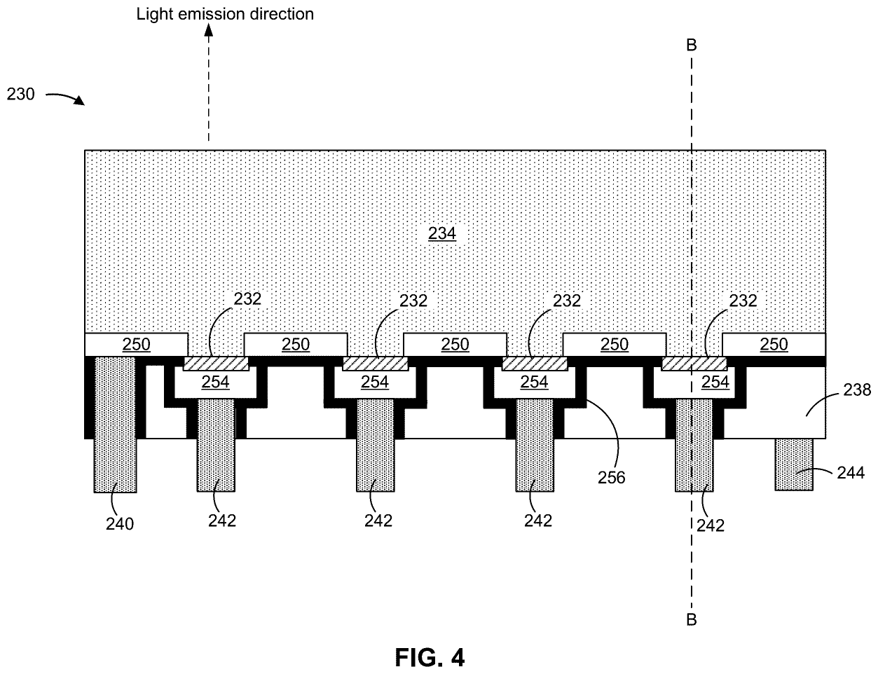

FIG. 4 is a diagram illustrating a cross-sectional view of the example VCSEL device 230 of FIG. 2 taken along line A-A. As shown, the VCSEL device 230 may include the substrate 234 and the plurality of VCSELs 232 disposed on the substrate 234. The VCSELs 232 may be configured as mesa structures or as planar structures. As described elsewhere herein, a VCSEL 232 may include a bottom mirror (e.g., a bottom DBR), an active region, and a top mirror (e.g., a top DBR), among other layers. The VCSELs 232 may be in a bottom-emitting (or “back-emitting”) configuration (e.g., a light emission direction of the VCSELs 232 may be through the substrate 234). However, in some implementations, the plurality of VCSELs 232 may be in a top-emitting configuration.

The VCSEL device 230 may include a conductive anode layer 250. The anode layer 250 may include a continuous layer (e.g., a plate) that runs along a surface of the substrate 234 having a plurality of openings that surround each VCSEL 232 to define apertures for each VCSEL 232. Accordingly, anodes of all of the VCSELs 232 may be tied together by the anode layer 250. For example, the anode layer 250 may be electrically connected to respective bottom mirrors of each of the VCSELs 232 (e.g., via ohmic contacts). In some implementations, other configurations of the anode layer 250 may be utilized. For example, the VCSEL device 230 may include multiple discrete anode layers (e.g., anode electrodes), and each anode layer may connect to a respective set of VCSELs 232 (e.g., one or more VCSELs 232). The anode layer 250 may include a metal layer, as described herein. In some implementations, a conductive semiconductor layer 252 (shown in FIG. 6) may be disposed on the substrate 234 between the anode layer 250 and the VCSELs 232. Thus, the anode layer 250 may be electrically connected to the VCSELs 232 via the conductive semiconductor layer 252. The conductive semiconductor layer 252 may include a doped semiconductor material, such as n-GaAs or p-GasAs.

The VCSEL device 230 may include at least one cathode electrode 254. The cathode electrode 254 may be over at least a portion of one or more VCSELs 232 and may be electrically connected to the one or more VCSELs 232. As an example, the cathode electrode 254 may be electrically connected to respective top mirrors of each of the one or more VCSELs 232 (e.g., via ohmic contacts). The anode layer 250 and a cathode electrode 254 may be electrically separated (e.g., by a dielectric), except when a VCSEL 232 is turned on. Accordingly, electrical current may flow from the anode layer 250, through the one or more VCSELs 232, to the cathode electrode 254. In some implementations, as shown, the cathode electrode 254 may fully cover top surfaces of the one or more VCSEL 232, which provides a bottom-emitting configuration for the one or more VCSELs 232.

The cathode electrode 254 may be electrically connected to a single VCSEL 232, a row of VCSELs 232 (as shown), multiple rows of VCSELs 232, a cluster of VCSELs 232, or all of the VCSELs 232. In some implementations, the VCSEL device 230 may include a plurality of cathode electrodes 254. Each cathode electrode 254 may be electrically connected to a respective set of VCSELs 232 (e.g., one or more VCSELs 232), thereby enabling control of the set of VCSELs 232 independently from other sets of VCSELs 232.

As described herein, the VCSEL device 230 may include the ground layer 238. The ground layer 238 may be disposed on the substrate 234 (e.g., located somewhere in the three-dimensional stack up of the set of layers 236). For example, the ground layer 238 may cover the VCSEL device 230 (e.g., except at locations where the presence of the ground layer 238 would short out the anode layer 250 or the cathode electrode 254). The ground layer 238 may include a conductive layer, such as a metal layer (e.g., a copper layer, a gold layer, or the like). For example, the ground layer 238 may include an additional metal layer distinct from the anode layer 250 and the cathode electrode 254.

The ground layer 238 may be electrically isolated from the anode layer 250 and the cathode electrode 254. For example, the VCSEL device 230 may include one or more isolation layers 256 that electrically isolate the ground layer 238 from the anode layer 250 and the cathode electrode 254. As an example, the isolation layer(s) 256 may be present at any area where the anode layer 250 and the cathode electrode 254 would otherwise overlap or interface. An isolation layer 256 may include a dielectric layer, which may include SiN, Si₃N₄, or SiO₂. An isolation layer 256 may be relatively thin (e.g., as thin as 0.5 micrometers).

In some implementations, the ground layer 238 may be on top of the anode layer 250. For example, as shown, the ground layer 238 may be on (e.g., may cover) the anode layer 250 and the cathode electrode 254. Here, an isolation layer 256 may be disposed between the ground layer 238, and the anode layer 250 and the cathode electrode 254 (e.g., the isolation layer 256 may be disposed below the ground layer 238 and above the anode layer 250 and the cathode electrode 254). As another example, the ground layer 238 may be between the anode layer 250 and the cathode electrode 254. Here, a first isolation layer 256 may be between the anode layer 250 and the ground layer 238, and a second isolation layer 256 (not shown) may be between the ground layer 238 and the cathode electrode 254. In some implementations, the ground layer 238 may be underneath the anode layer 250. For example, the ground layer 238 may be between the substrate 234 and the anode layer 250 (e.g., between the conductive semiconductor layer 252 and the anode layer 250). Here, a first isolation layer 256 may be between the substrate 234 and the ground layer 238, and a second isolation layer 256 (not shown) may be between the ground layer 238 and the anode layer 250. In examples in which the ground layer 238 is between the anode layer 250 and the cathode electrode 254, or underneath the anode layer 250, the ground layer 238 and the isolation layer(s) 256 may be patterned (e.g., with one or more openings) to provide a current path from the anode layer 250 to the cathode electrode 254.

As shown, an opening in the ground layer 238 may surround a VCSEL 232, and a second interconnect 242, electrically connected to a cathode electrode 254, may extend through the opening. The second interconnect 242 may electrically connect the cathode electrode 254 and the carrier 210. As shown, the anode layer 250 may be exposed at an edge of the VCSEL device 230 (e.g., the anode layer 250 is uncovered by the ground layer 238). A first interconnect 240 may electrically connect to the anode layer 250 (e.g., to a contact pad of the anode layer 250). The first interconnect 240 may electrically connect the anode layer 250 and the carrier 210. As shown, a third interconnect 244 may electrically connect to the ground layer 238. The third interconnect 244 may electrically connect the ground layer 238 and the carrier 210. The interconnects 240, 242, 244 may extend from the VCSEL device 230, as shown, and/or may extend from the carrier 210 (e.g., to contact pads on the VCSEL device 230).

As indicated above, FIG. 4 is provided as an example. Other examples may differ from what is described with regard to FIG. 4.

FIG. 5 is a diagram illustrating a cross-sectional view of the example VCSEL device 230 shown in FIG. 4, taken along line B-B. As shown, a row of VCSELs 232 may be connected to a single cathode electrode 254. In some implementations, the second interconnects 242 may be located at each of the VCSELs 232 (e.g., a quantity of second interconnects 242 may equal a quantity of VCSELs 232) or, as shown, at a subset of the VCSELs 232 (e.g., a quantity of second interconnects 242 may be less than a quantity of VCSELs 232).

As indicated above, FIG. 5 is provided as an example. Other examples may differ from what is described with regard to FIG. 5.

FIG. 6 is a diagram illustrating a cross-sectional view of the example emitter assembly 200 of FIG. 2 taken along line C-C. As shown, the carrier 210 (e.g., a driver chip) may include a switch 258 electrically connected to a cathode electrode 254 and the ground layer 238. The carrier 210 may be configured to provide driving signals to the switch 258 to cause opening or closing of the switch 258. The switch 258 may include a transistor, a field effect transistor (FET), a metal oxide semiconductor FET (MOSFET), or the like. Each cathode electrode 254 may be connected to a respective switch 258, or multiple cathode electrodes may be connected to a switch. Accordingly, a set of VCSELs 232 associated with a cathode electrode 254 may be controlled (e.g., turned on and turned off) via a switch 258 connected to the cathode electrode 254.

Closing the switch 258 may cause the decoupling capacitor 220 to discharge current (e.g., an anode signal) that flows from a contact 260a of the decoupling capacitor 220 through the carrier 210 (e.g., through an anode signal plane of the carrier 210), and from the carrier 210 through the anode layer 250 via one or more of the first interconnects 240. From the anode layer 250, current may flow through one or more VCSELs 232 to the cathode electrode 254, and from the cathode electrode 254 to the carrier 210 via one or more of the second interconnects 242. Current returning from the carrier 210 (e.g., a ground return signal) may flow through the ground layer 238 and to the ground plane 262 of the carrier 210 via one or more of the third interconnects 244 (e.g., some of which provide inputs to the ground layer 238 and some of which provide outputs from the ground layer 238), and then to a contact 260b (e.g., a ground contact) of the decoupling capacitor 220. Ground plane 262 may be connected to the interconnects 244 and to the contact 260 by electrical paths (not shown) in or on the carrier 210.

Thus, the ground layer 238 may provide a ground path of the VCSEL device 230, and may return looping current. For example, the ground layer 238 may provide a current looping path near to, but in an opposite direction to, a driving current path through the anode layer 250. As an example, the anode layer 250 may be configured such that current discharged from the decoupling capacitor 220 may flow through the anode layer 250 in a first direction (e.g., a current flow path through the anode layer 250 is in the first direction). Continuing with the example, the cathode electrode 254 may be configured such that current may flow from the anode layer 250 through one or more VCSELs 232 (electrically connected to the cathode electrode 254) to the cathode electrode 254. Continuing further with the example, the ground layer 238 may be configured such that current flows from the cathode electrode 254 through the ground layer 238 (e.g., through the carrier 210 and then through the ground layer 238), in a second direction opposite the first direction, to the decoupling capacitor 220 (e.g., a current looping path through the ground layer 238 is in the second direction). In other words, current flow through the anode layer 250 and current flow through the ground layer 238 may be in opposite directions to each other.

The first direction may refer to a general direction of current flow through the anode layer 250 from a first end of the VCSEL device 230 toward a second, opposite end of the VCSEL device 230. Thus, current flowing in the first direction may flow through the anode layer 250 taking various paths in various directions, provided that the current flow is in a direction from the first end toward the second end and not toward the first end. Similarly, the second direction may refer to a general direction of current flow through the ground layer 238 from the second end toward the first end. Thus, current flowing in the second direction may flow through the ground layer 238 taking various paths in various directions, provided that the current flow is in a direction from the second end toward the first end and not toward the second end.

Accordingly, the ground layer 238 may also be referred to as a ground current looping layer, or the like. Current flowing through the ground layer 238 in the second direction may provide mutual inductance cancellation with current flowing through the anode layer 250 in the first direction (e.g., when an isolation layer 256, not shown in FIG. 6, between the anode layer 250 and the ground layer 238 is sufficiently thin). This mutual inductance cancellation (e.g., cancellation of magnetic flux stored in the looping area) may lower inductance in the driving current path (e.g., a driving circuit external to the decoupling capacitor 220 starting from the contact 260a) through the anode layer 250, thereby improving a performance of the VCSEL device 230 and facilitating high-speed operation of the VCSEL device 230. Furthermore, the ground layer 238 being integrated into the VCSEL device 230 provides denser component integration, provides a more compact looping area, and facilitates a reduction of external routing for the VCSEL device 230 to reduce an overall package size. The ground layer 238 may also provide improved heat spreading for the VCSEL device 230 and/or may lower a thermal resistance of the VCSEL device 230.

As indicated above, FIG. 6 is provided as an example. Other examples may differ from what is described with regard to FIG. 6.

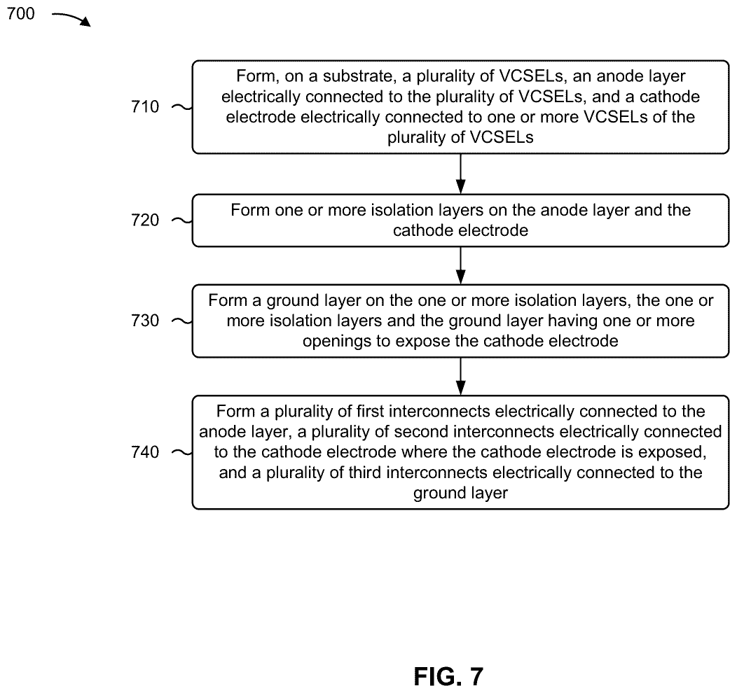

FIG. 7 is a flowchart of an example process 700 associated with manufacturing a VCSEL device with an integrated ground layer. In some implementations, one or more process blocks of FIG. 7 may be performed by various semiconductor manufacturing equipment.

As shown in FIG. 7, process 700 may include forming, on a substrate, a plurality of VCSELs, an anode layer electrically connected to the plurality of VCSELs, and a cathode electrode electrically connected to one or more VCSELs of the plurality of VCSELs (block 710). For example, the plurality of VCSELs may be formed on the substrate (e.g., by growing a set of epitaxial layers), a metal layer may be deposited on the plurality of VCSELs, and the metal layer may be patterned to form the anode layer and the cathode electrode (e.g., a plurality of cathode electrodes). As an example, a VCSEL device may include multiple cathode electrodes, where VCSELs that share a cathode electrode may be referred to as a “sub-array” or a “channel.”

As further shown in FIG. 7, process 700 may include forming one or more isolation layers on the anode layer and the cathode electrode (block 720). As further shown in FIG. 7, process 700 may include forming a ground layer on the one or more isolation layers, the one or more isolation layers and the ground layer having one or more openings to expose the cathode electrode (block 730). In some implementations, forming the isolation layer(s) may include depositing the isolation layer(s) on the anode layer and the cathode electrode, and patterning the isolation layer(s) to form the one or more openings in the isolation layer(s). In some implementations, forming the ground layer may include depositing the ground layer on the isolation layer(s), and patterning the ground layer to form the one or more openings in the ground layer. In some implementations, the one or more openings may be formed in the isolation layer(s) and in the ground layer as part of a single processing step.

As further shown in FIG. 7, process 700 may include forming a plurality of first interconnects electrically connected to the anode layer, a plurality of second interconnects electrically connected to the cathode electrode where the cathode electrode is exposed, and a plurality of third interconnects electrically connected to the ground layer (block 740). The first, second, and third interconnects may be formed as part of a single processing step or in respective processing steps.

Process 700 may include additional implementations, such as in connection with one or more other processes described elsewhere herein. Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In some implementations, process 700 may include forming a first isolation layer on the anode layer, forming the ground layer on the first isolation layer, forming a second isolation layer on the ground layer, and forming the cathode electrode on the second isolation layer. For example, forming one of the aforementioned layers may include depositing and/or patterning the layer, in a similar manner as described above. As an example, the first isolation layer, the ground layer, and the second isolation layer may be patterned to form one or more openings to expose the plurality of VCSELs (e.g., to provide a current path from the anode layer to the cathode electrode). For example, the cathode electrode may fill the one or more openings. In some implementations, a quantity of openings may correspond to a quantity of cathode electrodes.

In some implementations, process 700 may include forming a first isolation layer on the plurality of VCSELs, forming the ground layer on the first isolation layer, forming a second isolation layer on the ground layer, and forming the anode layer and the cathode layer on the second isolation layer. For example, forming one of the aforementioned layers may include depositing and/or patterning the layer, in a similar manner as described above. As an example, the first isolation layer, the ground layer, and the second isolation layer may be patterned to form one or more openings to expose the plurality of VCSELs and to expose a conductive semiconductor layer formed on the substrate (e.g., to provide a current path from the anode layer to the cathode electrode). For example, the anode layer and the cathode electrode may fill the one or more openings.

In some implementations, an optical source may include the emitter assembly 200 and/or the VCSEL device 230. In some implementations, an optical system may include the emitter assembly 200 and/or the VCSEL device 230. Moreover, the optical system may include one or more lenses, one or more optical elements (e.g., diffractive optical elements, refractive optical elements, or the like), one or more reflector elements, and/or one or more optical sensors, among other examples. In some implementations, the emitter assembly 200 and/or the VCSEL device 230 may be included in (e.g., may be configured for use in) a lidar system or a three-dimensional sensing system.

According to some implementations, a method may include generating an optical pulse for lidar using the emitter assembly 200 and/or the VCSEL device 230; receiving a signal based on a reflection of the optical pulse from an object; and/or determining a distance and/or a velocity of the object based on the signal. According to some implementations, a method may include generating (or forming) an array of light spots for three-dimensional sensing using the emitter assembly 200 and/or the VCSEL device 230; receiving signals based on reflection of the light spots from an object; and/or generating a depth map based on the signals. According to some implementations, a method may include generating (or forming) a light pattern for three-dimensional sensing using the emitter assembly 200 and/or the VCSEL device 230; receiving signals based on reflection of the light pattern from an object; and/or generating a depth map based on the signals.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” “bottom,” “top,” “underneath,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An emitter assembly, comprising:
a carrier comprising a ground plane;
a decoupling capacitor electrically connected to the ground plane; and
a vertical cavity surface emitting laser (VCSEL) device on the carrier and electrically connected to the ground plane and the decoupling capacitor, the VCSEL device comprising:
a substrate;
a plurality of VCSELs on the substrate;
at least one anode layer on the substrate and electrically connected to the plurality of VCSELs;
one or more first interconnects that electrically connect the at least one anode layer and the carrier;
a cathode electrode over at least a portion of one or more VCSELs, of the plurality of VCSELs, and electrically connected to the one or more VCSELs;
one or more second interconnects that electrically connect the cathode electrode and the carrier;
a ground layer electrically connected to the ground plane and electrically isolated from the at least one anode layer and the cathode electrode by one or more isolation layers; and
one or more third interconnects that electrically connect the ground layer and the carrier.

2. The emitter assembly of claim 1, wherein the ground layer includes one or more openings and the one or more second interconnects extend respectively through the one or more openings.

3. The emitter assembly of claim 1, wherein a current flow path through the at least one anode layer is in a first direction and a current looping path through the ground layer is in a second direction opposite the first direction.

4. The emitter assembly of claim 1, wherein the carrier comprises an integrated circuit chip.

5. The emitter assembly of claim 1, wherein the ground layer is on the at least one anode layer and the cathode electrode, and
wherein the one or more isolation layers include an isolation layer between:
the ground layer, and
the at least one anode layer and the cathode electrode.

6. The emitter assembly of claim 1, wherein the ground layer is between the at least one anode layer and the cathode electrode, and
wherein the one or more isolation layers include a first isolation layer between the at least one anode layer and the ground layer, and a second isolation layer between the ground layer and the cathode electrode.

7. The emitter assembly of claim 1, wherein the ground layer is underneath the at least one anode layer, and
wherein the one or more isolation layers include an isolation layer between the ground layer and the at least one anode layer.

8. The emitter assembly of claim 1, further comprising:
a conductive semiconductor layer on the substrate,
wherein the plurality of VCSELs are on the conductive semiconductor layer, and
wherein the at least one anode layer is on the conductive semiconductor layer and electrically connected to the plurality of VCSELs via the conductive semiconductor layer.

9. The emitter assembly of claim 1, wherein the VCSEL device is in a flip chip configuration on the carrier.

10. An emitter assembly, comprising:
a carrier comprising a ground plane;
a decoupling capacitor electrically connected to the ground plane; and
a vertical cavity surface emitting laser (VCSEL) device disposed on the carrier and electrically connected to the ground plane and the decoupling capacitor, the VCSEL device comprising:
a substrate;
a plurality of VCSELs on the substrate;
an anode layer on the substrate,
wherein current to be discharged from the decoupling capacitor is to flow through the anode layer in a first direction;
a cathode electrode over at least a portion of one or more VCSELs of the plurality of VCSELs,
wherein current is to flow from the anode layer through the one or more VCSELs to the cathode electrode, and from the cathode electrode to the carrier; and
a ground layer electrically isolated from the anode layer and the cathode electrode by one or more isolation layers,
wherein current returning from the carrier is to flow through the ground layer in a second direction opposite the first direction.

11. The emitter assembly of claim 10, wherein current to flow through the ground layer in the second direction is to provide mutual inductance cancellation with current to flow through the anode layer in the first direction.

12. The emitter assembly of claim 10, wherein the ground layer is on the anode layer and the cathode electrode, and
wherein the one or more isolation layers include an isolation layer between:
the ground layer, and
the anode layer and the cathode electrode.

13. The emitter assembly of claim 10, wherein the ground layer is between the anode layer and the cathode electrode, and
wherein the one or more isolation layers include a first isolation layer between the anode layer and the ground layer, and a second isolation layer between the ground layer and the cathode electrode.

14. The emitter assembly of claim 10, wherein the ground layer is underneath the anode layer, and
wherein the one or more isolation layers include an isolation layer between the ground layer and the anode layer.

15. The emitter assembly of claim 10, wherein the anode layer is electrically connected to the decoupling capacitor, and
wherein the ground layer is electrically connected to the decoupling capacitor.

16. The emitter assembly of claim 10, wherein the plurality of VCSELs are in a bottom-emitting configuration.

17. A vertical cavity surface emitting laser (VCSEL) device, comprising:
a substrate;
a plurality of VCSELs on the substrate;
an anode layer on the substrate and electrically connected to the plurality of VCSELs;
a cathode electrode over at least a portion of one or more VCSELs, of the plurality of VCSELs, and electrically connected to the one or more VCSELs; and
a ground layer electrically isolated from the anode layer and the cathode electrode by one or more isolation layers,
wherein the ground layer is on the anode layer and the cathode electrode, between the anode layer and the cathode electrode, or underneath the anode layer.

18. The VCSEL device of claim 17, wherein a current flow path through the anode layer is in a first direction and a current looping path through the ground layer is in a second direction opposite the first direction.

19. The VCSEL device of claim 17, wherein the anode layer is electrically connected to a respective bottom mirror of each of the plurality of VCSELs and the cathode electrode is electrically connected to a respective top mirror of each of the one or more VCSELs.

20. The VCSEL device of claim 17, wherein the cathode electrode is one of a plurality of cathode electrodes.
